(19) United States
(12) Patent Application Publication
(10) Pub. No.: US 2010/0258778 A1
(43) Pub. Date: Oct. 14, 2010

(54) RESISTIVE MEMORY DEVICE AND METHOD FOR MANUFACTURING THE SAME

(76) Inventor: Min-Gyu SUNG, Gyeonggi-do (KR)

Correspondence Address: IP & T Law Firm PLC, 7700 Little River Turnpike, Suite 207, Annandale, VA, 22003, US

(21) Appl. No.: 12/617,188

(22) Filed: Nov. 12, 2009

(30) Foreign Application Priority Data
Apr. 13, 2009 (KR) 10-2009-0031805

(51) Int. Cl. H01L 45/00; H01L 21/30

(52) U.S. Cl. 257/2; 438/104; 257/43; 257/E45.002; 257/E21.211

(57) ABSTRACT

A resistive memory device includes a bottom electrode, a resistive layer formed over the bottom electrode and having a structure in which a first resistive layer having an amorphous phase and a second resistive layer having a polycrystal phase are sequentially stacked, and a top electrode formed over the second resistive layer.

### CROSS-REFERENCE(S) TO RELATED APPLICATIONS

The present application claims priority to Korean Patent Application No(s). 10-2009-0031805, filed on Apr. 13, 2009, the disclosure of which is incorporated herein by reference in its entirety.

### BACKGROUND OF THE INVENTION

Exemplary embodiments of the present invention relate to technology for manufacturing a semiconductor device, and more particularly, to a resistive memory device, such as a nonvolatile ReRAM (resistive random access memory), which utilizes change of resistance, and a method for manufacturing the same.

Recently, research for developing next generation memory devices capable of replacing a DRAM and a flash memory has actively been conducted.

One of these next generation memory devices is a resistive memory device, which employs a variable resistance material in such a manner that a resistance abruptly changes depending upon an applied voltage, so the resistive memory device can be switched between two different resistances. Examples of variable resistance material having this characteristic include a binary oxide including a transition metal oxide or a perovskite-based material.

FIG. 1 is a cross-sectional view illustrating a resistive memory device according to the conventional art.

Referring to FIG. 1, a conventional resistive memory device includes a substrate 11 which has a predetermined structure formed therein, an insulation layer 12 which is formed on the substrate 11, a plug 13 which passes through the insulation layer 12 and is connected with the substrate 11, a bottom electrode 14 which is placed on the insulation layer 12 and is connected with the plug 13, a resistive layer 15 which is formed on the bottom electrode 14, and a top electrode 16 which is formed on the resistive layer 15. The resistive layer 15 has a polycrystal phase and includes oxygen vacancies or metal vacancies therein.

The switching mechanism of the resistive memory device constructed as mentioned above will be briefly described below.

When a bias is applied to the bottom electrode 14 and the top electrode 16, depending upon the applied bias, filamentary current paths are generated in the resistive layer 15 due to the presence of the vacancies, or previously generated filamentary current paths are vanished due to removal of the vacancies. The resistive layer 15 exhibits two distinguishable resistive states respectively resulting from the generation and vanishment of the filamentary current paths. That is to say, the generation of the filamentary current paths represents a low resistance state, and the vanishment of the filamentary current paths represents a high resistance state. Here, the operation in which the filamentary current paths are generated in the resistive layer 15 and the low resistance state results is called a set operation, and the operation in which the previously generated filamentary current paths are vanished and the high resistance state results is called a reset operation.

In a conventional resistive memory device, since the resistive layer 15 has polycrystals and the filamentary current paths are generated along the interfaces of the polycrystals, that is, grain boundaries, a problem arises where set/reset current distribution becomes non-uniform. This is because the distribution of grain boundaries in the resistive layer 15 is non-uniform, and the distribution of the filamentary current paths generated along the grain boundaries becomes non-uniform as well.

In order to realize a uniform distribution of set/reset current, the thickness of the resistive layer 15 should be reduced. In this regard, if the thickness of the resistive layer 15 is reduced, leakage current increases along the grain boundaries in the resistive layer 15. This is because leakage current conduction paths are shortened as the thickness of the resistive layer 15 is reduced. Due to this fact, a problem arises where the variable resistance characteristics of the resistive layer 15 are degraded. Degradation of the variable resistance characteristics of the resistive layer 15 increases a reset current and a reset time.

If the thickness of the resistive layer 15 is increased so as to suppress generation of leakage current in the resistive layer 15, set/reset current distribution characteristics are degraded. Also, the degree of integration of the resistive memory device decreases.

Accordingly, in order to allow the resistive memory device to stably secure switching characteristics required in a memory, a method for reducing a reset current and a reset time, and at the same time, uniformly controlling set/reset current distribution is contemplated.

### SUMMARY OF THE INVENTION

An embodiment of the present invention is directed to providing a resistive memory device which can stably secure switching characteristics required in a memory by reducing a reset current and a reset time, and at the same time, obtaining uniform set/reset current distribution, and a method for manufacturing the same.

An embodiment of the present invention is directed to a resistive memory device, the device comprising a bottom electrode, a resistive layer formed over the bottom electrode and having a structure in which a first resistive layer having an amorphous phase and a second resistive layer having a polycrystal phase are sequentially stacked, and a top electrode formed over the second resistive layer.

The first and second resistive layers may contain a transition metal oxide.

The first and second resistive layers may be formed of the same material or different materials.

The transition metal oxide may include any one selected from the group consisting of a nickel oxide (NiO), a titanium oxide (TiO), a hafnium oxide (WO), a niobium oxide (NbO), a zirconium oxide (ZrO), a tungsten oxide (WO) and a cobalt oxide (CoO).

The thickness of the second resistive layer may be the same as or greater than a thickness of the first resistive layer.

The resistive layer may have a density of vacancies per unit volume that gradually increases from a lower end toward an upper end of the resistive layer.

The density of vacancies per unit volume in the first resistive layer may be greater than a density of vacancies per unit volume in the second resistive layer.

Another embodiment of the present invention is directed to a method for manufacturing a resistive memory device, the method comprising forming a bottom electrode, forming a first resistive layer which has an amorphous phase, over the bottom electrode, forming a second resistive layer which has a polycrystal phase, over the first resistive layer and forming a top electrode over the second resistive layer.

Forming the first resistive layer may be conducted through atomic layer deposition.

Forming the second resistive layer may be conducted through physical vapor deposition or chemical vapor deposition.

The first and second resistive layers may contain a transition metal oxide.

The first and second resistive layers may be formed of the same material or different materials.

The transition metal oxide may include any one selected from the group consisting of a nickel oxide (NiO), a titanium oxide (TiO), a hafnium oxide (HfO), a niobium oxide (NbO), a zirconium oxide (ZrO), a tungsten oxide (WO) and a cobalt oxide (CoO).

The thickness of the second resistive layer may be the same as or greater than a thickness of the first resistive layer.

### BRIEF DESCRIPTION OF THE DRAWINGS

FIG. 1 is a cross-sectional view illustrating a resistive memory device according to the conventional art.

FIG. 2 is a cross-sectional view illustrating a resistive memory device, in accordance with a first embodiment of the present invention.

FIG. 3 is a cross-sectional view illustrating a resistive memory device, in accordance with a second embodiment of the present invention.

FIGS. 4a through 4c are cross-sectional views illustrating the processes of a method for manufacturing a resistive memory device, in accordance with a third embodiment of the present invention.

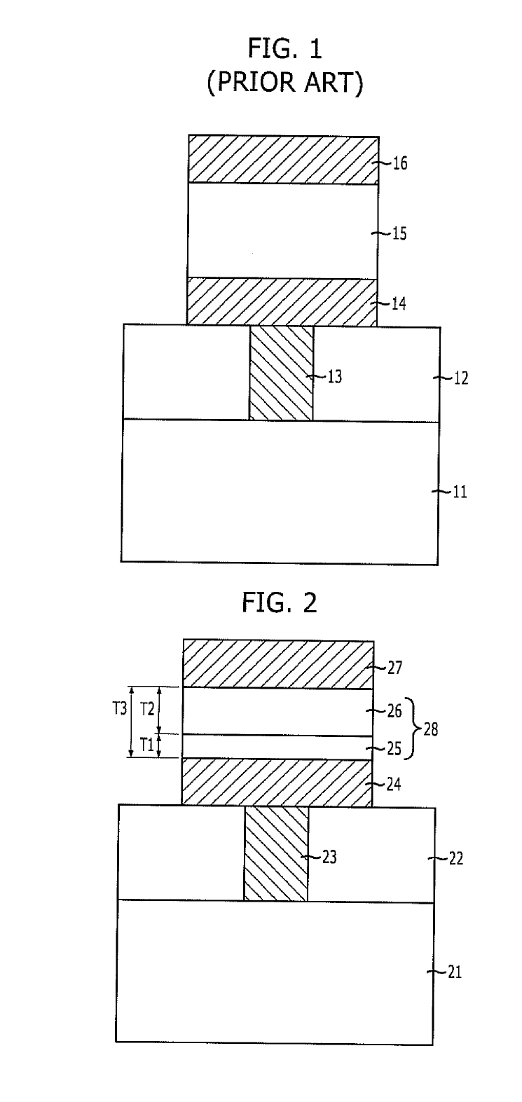

### DESCRIPTION OF SPECIFIC EMBODIMENTS

Other objects and advantages of the present invention can be understood by the following description, and become apparent with reference to the embodiments of the present invention.

Referring to the drawings, the illustrated thickness of layers and regions are exaggerated to facilitate explanation. When a first layer is referred to as being “on” a second layer or “on” a substrate, it could mean that the first layer is formed directly on the second layer or the substrate, or it could also mean that a third layer may exist between the first layer and the substrate. Furthermore, the same or like reference numerals represent the same or like constituent elements, although they appear in different embodiments or drawings of the present invention.

An embodiment of the present invention relates to a resistive memory device, such as a nonvolatile ReRAM (resistive random access memory), which utilizes change of resistance, and a method for manufacturing the same. In particular, the embodiment of the present invention relates to a resistive memory device stably secures switching characteristics required in a memory by reducing a reset current and a reset time, and at the same time obtaining uniform set/reset current distribution and a method for manufacturing the same. To this end, according to an embodiment of the present invention, a resistive layer is formed to have a structure in which a first resistive layer having an amorphous phase and a second resistive layer having a polycrystal phase are sequentially stacked. The resistive layer exhibits two distinguishable resistive states respectively resulting from the fact that, depending upon a bias applied to the resistive layer, filamentary current paths are generated due to the presence of the vacancies or previously generated filamentary current paths are vanished due to removal of the vacancies. That is, the generation of the filamentary current paths represents a low resistance state, and the vanishment of the filamentary current paths represents a high resistance state. Here, the operation which results in the low resistance state is called a set operation, and the operation which results in the high resistance state is called a reset operation.

FIG. 2 is a cross-sectional view illustrating a resistive memory device, in accordance with a first embodiment of the present invention.

Referring to FIG. 2, the resistive memory device, according to the embodiment, includes a substrate 21 which has a predetermined structure formed therein, an insulation layer 22 which is formed on the substrate 21, a plug 23 which passes through the insulation layer 22 and is connected with the substrate 21, a bottom electrode 24 which is placed on the insulation layer 22 and is connected with the plug 23, a resistive layer 28 which is formed on the bottom electrode 24, and a top electrode 27 which is formed on the resistive layer 28.

The resistive layer 28 includes a first resistive layer 25, which is formed on the bottom electrode 24 and has an amorphous phase, and a second resistive layer 26 which is formed on the first resistive layer 25 and has a polycrystal phase. That is to say, the resistive layer 28 has a structure in which the first resistive layer 25 having the amorphous phase and the second resistive layer 26 having the polycrystal phase are sequentially stacked. Through this, a reset current and a reset time can be reduced, and at the same time the uniformity of set/reset current distribution can be improved.

Hereafter, the structure of an exemplary memory device of the present invention will be described in terms of the reset current and reset time.

If leakage current generated in the resistive layer 28 is decreased, a reset current and a reset time of the resistive memory device can be reduced. To this end, since the resistive layer 28 has the first resistive layer 25 having the amorphous phase, it is possible to prevent leakage current from being generated in the resistive layer 28.

In detail, since the first resistive layer 25 having the amorphous phase does not have grain boundaries therein, conduction of leakage current due to the presence of grain boundaries can be prevented. In other words, generation of leakage current can be prevented. Therefore, even though leakage current is generated due to the presence of grain boundaries in the second resistive layer 26 having the polycrystal phase, because paths through which leakage current is conducted, that is, grain boundaries, do not exist in the first resistive layer 25, leakage current generated in the resistive layer 28 can be decreased.

Also, in general, when the thickness of the second resistive layer 26 having the polycrystal phase is decreased, leakage current increases since conduction paths of leakage current are shortened. In this regard, due to the fact that the resistive layer 28 has the first resistive layer 25 having the amorphous phase of a thickness T1, even though a thickness T2 of the second resistive layer 26 is decreased, it is possible to prevent leakage current from increasing in the resistive layer 28. Hence, the thickness T2 of the second resistive layer 26 can be decreased. As a consequence, a thickness T3 of the resistive layer 28 can be decreased, and through this, the degree of integration of the resistive memory device having the resistive layer 28 can be elevated.

Hereafter, the structure of an exemplary resistive memory device of the present invention will be described in terms of the uniformity of set/reset current distribution.

As described above, since the resistive layer 28 has the first resistive layer 25 having the amorphous phase, the thickness T3 of the resistive layer 28 (specifically, the thickness T2 of the second resistive layer 26 having the polycrystal phase) can be decreased. If the thickness T2 of the second resistive layer 26 having the polycrystal phase is decreased in this way, the uniformity of set/reset current distribution can be improved. This is because non-uniformity of grain boundaries in the second resistive layer 26 can be decreased as the thickness T2 of the second resistive layer 26 having the polycrystal phase is decreased. That is to say, the distribution of grain boundaries in the second resistive layer 26 can be made uniform. Because filamentary current paths in the second resistive layer 26 are formed along the grain boundaries, the non-uniformity of the filamentary current paths is also decreased as the non-uniformity of the grain boundaries in the second resistive layer 26 is decreased. Accordingly, the uniformity of set/reset current distribution can be improved.

Also, due to the fact' that the first resistive layer 25 has the amorphous phase in which no grain boundaries exist, the filamentary current paths generated in the first resistive layer 25 can have uniform distribution. Through this, the uniformity of set/reset current distribution can be further improved.

As a result, the resistive layer 28 according to an embodiment of the present invention can reduce a reset current and a reset time, and at the same time improve the uniformity of set/reset current distribution. Also, the degree of integration of the resistive memory device having the resistive layer 28 can be elevated.

The first and second resistive layers 25 and 26 can include a transition metal oxide. In detail, the first and second resistive layers 25 and 26 can include any one selected from the group consisting of a nickel oxide (NiO), a titanium oxide (TiO), a hafnium oxide (HfO), a niobium oxide (NbO), a zirconium oxide (ZrO), a tungsten oxide (WO) and a cobalt oxide (CoO). The first and second resistive layers 25 and 26 including the transition metal oxide have vacancies, such as oxygen vacancies or metal vacancies.

The first and second resistive layers 25 and 26 can be formed of the same transition metal oxide or different transition metal oxides. It is preferred that the first and second resistive layers 25 and 26 be formed of the same transition metal oxide. The reason is that, when the first and second resistive layers 25 and 26 are formed of the same transition metal oxide, processes can be simplified, mass production (or productivity) of the resistive memory device can be ensured (or improved), and variable resistance characteristics of the resistive layer 28 can be easily controlled.

In addition, the first and second resistive layers 25 and 26 can be formed in such a way as to have the same thickness (T1=T2), or such that the thickness T2 of the second resistive layer 26 is greater than the thickness T1 of the first resistive layer 25 (T1<T2). It is preferred that the first and second resistive layers 25 and 26 be formed such that the thickness T2 of the second resistive layer 26 is greater than the thickness T1 of the first resistive layer 25, so that the resistive layer 28 can secure sufficiently variable resistance characteristics.

In addition to the first resistive layer 25 being formed to have the amorphous phase, in order to improve productivity, it is preferred that the first resistive layer 25 be formed to have a thickness less than 100 Å, for example, ranging from approximately 1 Å to approximately 100 Å. Moreover, it is preferred that the second resistive layer 26 be formed to have a thickness ranging from approximately 100 Å to approximately 1,000 Å in consideration of a reset current, a reset time and set/reset current distribution characteristics. For reference, a trade-off relationship is established between the set/reset current distribution and a reset current and a reset time depending upon the thickness T2 of the second resistive layer 26.

The bottom and top electrodes 24 and 27 can include a metal layer, a metal nitride layer or an alloy thereof which contains any one element selected from the group consisting of aluminum (Al), platinum (Pt), ruthenium (Ru), iridium (Ir), nickel (Ni), titanium (Ti), cobalt (Co), chrome (Cr), tungsten (W) and copper (Cu).

The resistive layer 28, according to an embodiment of the present invention can be formed as a single layer comprising the first resistive layer 25 having an amorphous phase rather than the stacked structure of the first and second resistive layers 25 and 26. However, in order to form a thin transition metal oxide layer having an amorphous phase, atomic layer deposition (ALD) should be used. In this regard, since a lot of processing time is required to form a thin layer through atomic layer deposition, productivity abruptly decreases. Also, even though the thin layer is formed through atomic layer deposition, since it is difficult to form the thin layer with proper thickness to have the amorphous phase, a problem occurs where it is difficult to sufficiently secure variable resistance characteristics required in a resistive memory device.

However, due to the fact that the resistive layer 28 is formed to have the stacked structure of the first and second resistive layers 25 and 26, variable resistance characteristics required in a resistive memory device can be sufficiently secured, and it is possible to prevent productivity from decreasing.

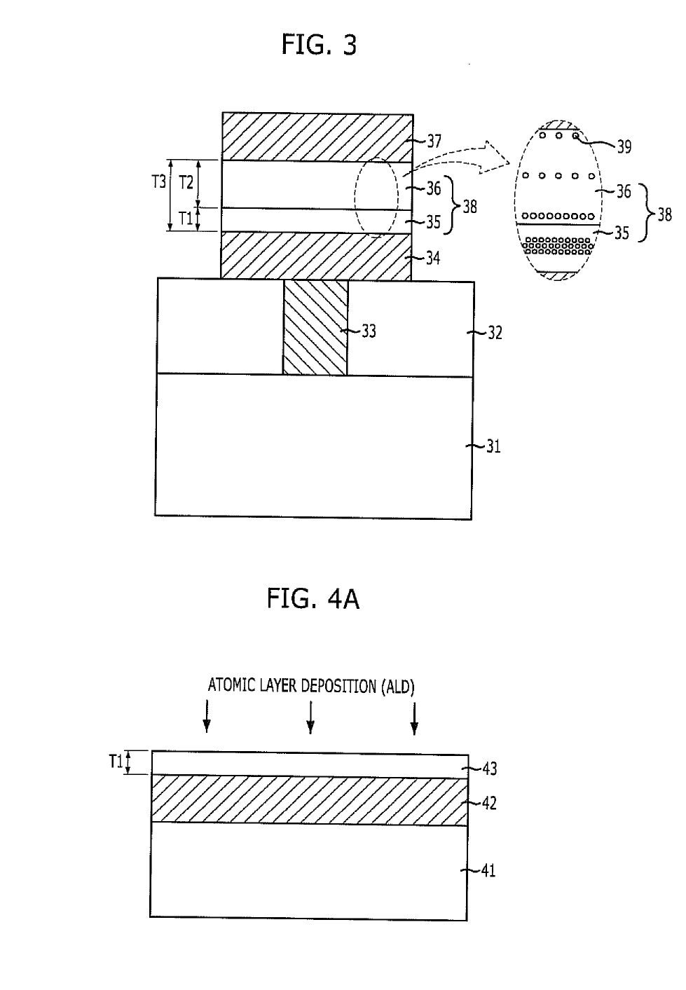

FIG. 3 is a cross-sectional view illustrating a resistive memory device, in accordance with a second embodiment of the present invention.

Referring to FIG. 3, the resistive memory device, according to the embodiment, includes a substrate 31 which has a predetermined structure formed therein, an insulation layer 32 which is formed on the substrate 31, a plug 33 which passes through the insulation layer 32 and is connected with the substrate 31, a bottom electrode 34 which is placed on the insulation layer 32 and is connected with the plug 33, a resistive layer 38 which is formed on the bottom electrode 34, and a top electrode 37 which is formed on the resistive layer 38.

The resistive layer 38 includes a first resistive layer 35 which is formed on the bottom electrode 34 and has an amorphous phase, and a second resistive layer 36 which is formed on the first resistive layer 35 and has a polycrystal phase. That is to say, the resistive layer 38 is formed to have a structure in which the first resistive layer 35 having the amorphous phase and the second resistive layer 36 having the polycrystal phase are sequentially stacked. Through this, a reset current and a reset time can be reduced and at the same time the uniformity of set/reset current distribution can be improved.

Hereafter, the structure of an exemplary resistive memory device of the present invention will be described in terms of the reset current and reset time.

If leakage current generated in the resistive layer 38 is decreased, the reset current and the reset time of the resistive memory device can be reduced. To this end, in the present invention, since the resistive layer 38 has the first resistive layer 35 having the amorphous phase, it is possible to prevent leakage current from being generated in the resistive layer 38.

Specifically, since the first resistive layer 35 having the amorphous phase does not have grain boundaries therein, conduction of leakage current due to the presence of grain boundaries can be prevented. Thus, generation of the leakage current can be prevented. Therefore, even though leakage current is generated due to the presence of grain boundaries in the second resistive layer 36 having the polycrystal phase, because paths through which leakage current is conducted (that is, grain boundaries) do not exist in the first resistive layer 35, leakage current generated in the resistive layer 38 can be decreased.

Also, in general, when the thickness of the second resistive layer 36 having the polycrystal phase is decreased, leakage current increases since conduction paths of leakage current are shortened. In this regard, in the present invention, due to the fact that the resistive layer 38 has the first resistive layer 35 having the amorphous phase of a thickness T1, even though a thickness T2 of the second resistive layer 36 is decreased, it is possible to prevent leakage current from increasing in the resistive layer 38. Hence, the thickness T2 of the second resistive layer 36 can be decreased. As a consequence, a thickness T3 of the resistive layer 38 can be decreased, and through this, the degree of integration of the resistive memory device having the resistive layer 38 can be elevated.

Hereafter, the structure of an exemplary resistive memory device of the present invention will be described in terms of the uniformity of set/reset current distribution.

As described above, since the resistive layer 38 according to an embodiment of the present invention has the first resistive layer 35 having the amorphous phase, the thickness T3 of the resistive layer 38, specifically, the thickness T2 of the second resistive layer 36 having the polycrystal phase can be decreased. If the thickness T2 of the second resistive layer 36 having the polycrystal phase is decreased as described above, the uniformity of set/reset current distribution can be improved. This is because non-uniformity of grain boundaries in the second resistive layer 36 can be decreased as the thickness T2 of the second resistive layer 36 having the polycrystal phase is decreased. That is to say, the distribution of grain boundaries in the second resistive layer 36 can be made uniform. Because filamentary current paths in the second resistive layer 36 are formed along the grain boundaries, the non-uniformity of the filamentary current paths is also decreased as the non-uniformity of the grain boundaries in the second resistive layer 36 is decreased. Accordingly, the uniformity of set/reset current distribution can be improved.

Also, due to the fact that the first resistive layer 35 has the amorphous phase in which no grain boundaries exist, the filamentary current paths generated in the first resistive layer 35 can have uniform distribution. Through this, the uniformity of set/reset current distribution can be further improved.

Thus, the resistive layer 38 according to an embodiment of the present invention can reduce a reset current and a reset time, and at the same time improve the uniformity of set/reset current distribution. Also, the degree of integration of the resistive memory device having the resistive layer 38 can be elevated.

The first and second resistive layers 35 and 36 can include a transition metal oxide. Specifically, the first and second resistive layers 35 and 36 can include any one selected from the group consisting of a nickel oxide (NiO), a titanium oxide (TiO), a hafnium oxide (HfO), a niobium oxide (NbO), a zirconium oxide (ZrO), a tungsten oxide (WO) and a cobalt oxide (CoO). The first and second resistive layers 35 and 36 including the transition metal oxide have therein vacancies 39, such as oxygen vacancies or metal vacancies.

The resistive layer 38 according to an embodiment of the present invention may have the density of vacancies 39 per unit volume being greater in the first resistive layer 35 than in the second resistive layer 36. Specifically, the density of vacancies 39 in the resistive layer 38 can be gradually decreased from the interface between the bottom electrode 34 and the resistive layer 38 toward the interface between the top electrode 37 and the resistive layer 38.

The reason why the density of vacancies 39 per unit volume is gradually decreased from the lower end of the resistive layer 38 toward the upper end of the resistive layer 38 is described below.

As aforementioned above, since generation or vanishment of filamentary current paths in the resistive layer 38 is caused due to the presence or absence of the vacancies 39 in the resistive layer 38, as the density of vacancies 39 per unit volume is decreased, the number of the filamentary current paths is also decreased. In this connection, the generation of the filamentary current paths starts from the bottom electrode 34, and the vanishment of the filamentary current paths starts from the top electrode 37. That is to say, the vanishment of the previously generated filamentary current paths is effected as the oxygen present at the interface between the resistive layer 38 and the top electrode 37 fills the vacancies 39 in the resistive layer 38.

Accordingly, in the case where the density of the vacancies 39 present in the second resistive layer 36 constituting the upper part of the resistive layer 38 is less than the density of the vacancies 39 present in the first resistive layer 35 constituting the lower part of the resistive layer 38, because the number of the filamentary current paths in the second resistive layer 36 is relatively small, it is easy to vanish the filamentary current paths, and as a result, a reset current and a reset time can be effectively reduced. Furthermore, since abnormal set/reset operation decreases, the uniformity of set/reset current distribution can be effectively improved.

The first and second resistive layers 35 and 36 can be formed of the same transition metal oxide or different transition metal oxides. It is preferred that the first and second resistive layers 35 and 36 be formed of the same transition metal oxide. The reason is that, when the first and second resistive layers 35 and 36 are formed of the same transition metal oxide, processes can be simplified, mass production (or productivity) of the resistive memory device can be ensured (or improved), and variable resistance characteristics of the resistive layer 38 can be easily controlled.

In addition, the first and second resistive layers 35 and 36 can be formed in such a way as to have the same thickness (T1=T2) or such that the thickness T2 of the second resistive layer 36 is greater than the thickness T1 of the first resistive layer 35 (T1<T2). It is preferred that the first and second resistive layers 35 and 36 be formed such that the thickness T2 of the second resistive layer 36 is greater than the thickness T1 of the first resistive layer 35, so that the resistive layer 38 can secure sufficiently variable resistance characteristics.

In addition to the fact that the first resistive layer 35 is formed to have the amorphous phase, in order to improve productivity, it is preferred that the first resistive layer 35 be formed to have a thickness less than 100 Å, for example, ranging from approximately 1 Å to approximately 100 Å. Moreover, it is preferred that the second resistive layer 36 be formed to have a thickness ranging from approximately 100 Å to approximately 1,000 Å in consideration of a reset current, a reset time and set/reset current distribution characteristics. For reference, a trade-off relationship is established between the set/reset current distribution and a reset current and a reset time depending upon the thickness T2 of the second resistive layer 36.

The bottom and top electrodes 34 and 37 can include a metal layer, a metal nitride layer or an alloy thereof which contains any one element selected from the group consisting of aluminum (Al), platinum (Pt), ruthenium (Ru), iridium (Ir), nickel (Ni), titanium (Ti), cobalt (Co), chrome (Cr), tungsten (W) and copper (Cu).

The resistive layer 38 according to the present invention can be formed as a single layer comprising the first resistive layer 35 having an amorphous phase rather than the stacked structure of the first and second resistive layers 35 and 36. However, in order to form a thin transition metal oxide layer having an amorphous phase, atomic layer deposition (ALD) should be used. In this regard, since a lot of processing time is required to form a thin layer through atomic layer deposition, productivity abruptly decreases. Also, even though the thin layer is formed through atomic layer deposition, since it is difficult to form the thin layer with proper thickness to have the amorphous phase, a problem occurs where it is difficult to sufficiently secure variable resistance characteristics required in a resistive memory device.

However, due to the fact that the resistive layer 38 is formed to have the stacked structure of the first and second resistive layers 35 and 36, variable resistance characteristics required in a resistive memory device can be sufficiently secured, and it is possible to prevent productivity from decreasing.

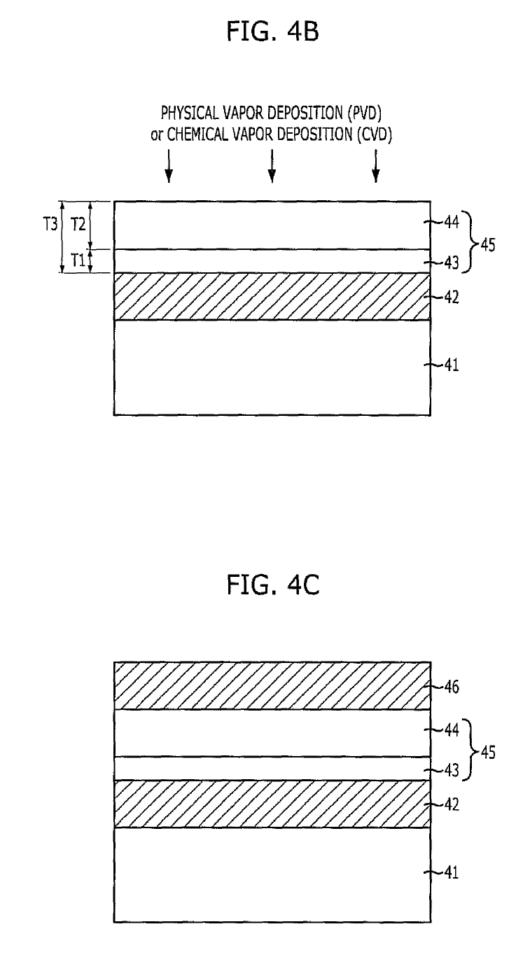

FIGS. 4a through 4c are cross-sectional views illustrating the processes of a method for manufacturing a resistive memory device in accordance with a third embodiment of the present invention. A method for manufacturing the resistive memory device shown in FIG. 2 will be described below.

Referring to FIG. 4a, a bottom electrode 42 is formed on a substrate 41 which has a predetermined structure formed therein. The bottom electrode 42 can be formed as a metal layer, a metal nitride layer or an alloy thereof which contains any one element selected from the group consisting of aluminum (Al), platinum (Pt), ruthenium (Ru), iridium (Ir), nickel (Ni), titanium (Ti), cobalt (Co), chrome (Cr), tungsten (W) and copper (Cu).

Next, a first resistive layer 43 having an amorphous phase is formed on the bottom electrode 42. The first resistive layer 43 can be formed of a transition metal oxide. The transition metal oxide may include any one selected from the group consisting of a nickel oxide (NiO), a titanium oxide (TiO), a hafnium oxide (WO), a niobium oxide (NbO), a zirconium oxide (ZrO), a tungsten oxide (WO) and a cobalt oxide (CoO). The first resistive layer 43 including the transition metal oxide has therein vacancies such as oxygen vacancies or metal vacancies.

In order to ensure that the first resistive layer 43 has the amorphous phase, it is preferred that the first resistive layer 43 be formed through atomic layer deposition (ALD). The atomic layer deposition indicates technology in which a material to deposit is deposited one atomic layer by one atomic layer through alternately supplying a source gas and a reaction gas into a chamber.

Also, in order not only to allow the first resistive layer 43 to have the amorphous phase, but also to improve the productivity of a resistive memory device, it is preferred that the first resistive layer 43 be formed to have a thickness ranging from approximately 1 Å to approximately 100 Å. For reference, the atomic layer deposition may be problematic in that a processing time and a processing cost increase when compared to a conventional deposition method, for example, physical vapor deposition (PVD) or chemical vapor deposition (CVD). In addition, even though the first resistive layer 43 is formed through atomic layer deposition, if a thickness T1 of the first resistive layer 43 exceeds 100 Å, the property of the first resistive layer 43 is likely to be changed from the amorphous phase to a polycrystal phase.

The first resistive layer 43 functions to reduce a reset current and a reset time by suppressing generation of leakage current in a resistive layer, and to decrease a thickness of a second resistive layer which will be formed through a subsequent process.

Referring to FIG. 4b, a second resistive layer 44 having a polycrystal phase is formed on the first resistive layer 43. Due to this fact, a resistive layer 45 can be formed to have a structure in which the first resistive layer 43 having the amorphous phase and the second resistive layer 44 having the polycrystal phase are sequentially stacked.

The second resistive layer 44 can be formed of a transition metal oxide. The transition metal oxide may include any one selected from the group consisting of a nickel oxide (NiO), a titanium oxide (TiO), a hafnium oxide (HfO), a niobium oxide (NbO), a zirconium oxide (ZrO), a tungsten oxide (WO) and a cobalt oxide (CoO). The second resistive layer 44 including the transition metal oxide has therein vacancies such as oxygen vacancies or metal vacancies.

The first and second resistive layers 43 and 44 can be formed of the same material or different materials. It is preferred that the first and second resistive layers 43 and 44 be formed of the same material. When the first and second resistive layers 43 and 44 are formed of the same material, processes can be simplified, mass production of the resistive memory device can be ensured, and variable resistance characteristics of the resistive layer 45 can be easily controlled.

The first and second resistive layers 43 and 44 can be formed in such a way as to have the same thickness (T1=T2) or such that the thickness T2 of the second resistive layer 44 is greater than the thickness T1 of the first resistive layer 43 (T1<T2). It is preferred that the thickness T2 of the second resistive layer 44 be greater than the thickness T1 of the first resistive layer 43, so that the resistive layer 45 can secure sufficiently variable resistance characteristics. For example, the second resistive layer 44 can be formed to have a thickness ranging from approximately 100 Å to approximately 1,000 Å.

In order to ensure mass production of the resistive memory device, it is preferred that the second resistive layer 44 be formed through physical vapor deposition or chemical vapor deposition. At this time, due to the presence of the first resistive layer 43, the deposition thickness T2 of the second resistive layer 44 can be decreased.

As a result, the deposition thickness of the resistive layer 45 can be decreased, and through this, the degree of integration of the resistive memory device can be elevated.

Referring to FIG. 4c, a top electrode 46 is formed on the second resistive layer 44. The top electrode 46 can be formed as a metal layer, a metal nitride layer or an alloy thereof which contains any one element selected from the group consisting of aluminum (Al), platinum (Pt), ruthenium (Ru), iridium (Ir), nickel (Ni), titanium (Ti), cobalt (Ca), chrome (Cr), tungsten (W) and copper (Cu).

As described above, due to the fact that the resistive layer 45 is formed to have a structure in which the first and second resistive layers 43 and 44 are stacked, the reset current and reset time of the resistive layer 45 can be reduced, and at the same time the uniformity of set/reset current distribution can be improved. Also, the degree of integration of the resistive memory device having the resistive layer 45 can be elevated. Furthermore, variable resistance characteristics required in a resistive memory device can be sufficiently secured, and it is possible to prevent productivity from decreasing.

As is apparent from the above description, exemplary embodiments of the present invention described herein provide advantages in that, since a resistive layer is formed to have a structure in which a first resistive layer having an amorphous phase and a second resistive layer having a polycrystal phase are stacked, a reset current and a reset time can be reduced, and the uniformity of reset/reset current distribution can be improved.

Also, exemplary embodiments of the present invention described herein provide advantages in that, since the density of vacancies per unit volume is gradually decreased from the bottom toward the top in the resistive layer in which the first and second resistive layers are stacked, the reset current and the reset time can be effectively reduced, and the uniformity of reset/reset current distribution can be effectively improved.

Further, exemplary embodiments of the present invention described herein provide advantages in that the switching characteristics of the resistive memory device can be stably secured and the productivity and the degree of integration of the resistive memory device can be elevated.

While the present invention has been described with respect to the specific embodiments, it will be apparent to those skilled in the art that various changes and modifications may be made without departing from the spirit and scope of the invention as defined in the following claims.

What is claimed is:

1. A resistive memory device comprising:
a bottom electrode;
a resistive layer formed over the bottom electrode and having a structure in which a first resistive layer having an amorphous phase and a second resistive layer having a polycrystal phase are sequentially stacked; and
a top electrode formed over the second resistive layer.

2. The resistive memory device of claim 1, wherein each of the first and second resistive layers comprises a transition metal oxide.

3. The resistive memory device of claim 2, wherein the first and second resistive layers are formed of the same material or different materials.

4. The resistive memory device of claim 2, wherein the transition metal oxide includes any one selected from the group consisting of a nickel oxide (NiO), a titanium oxide (TiO), a hafnium oxide (HfO), a niobium oxide (NbO), a zirconium oxide (ZrO), a tungsten oxide (WO) and a cobalt oxide (CoO).

5. The resistive memory device of claim 1, wherein a thickness of the second resistive layer is the same as or greater than a thickness of the first resistive layer.

6. The resistive memory device of claim 1, wherein the resistive layer has a density of vacancies per unit volume that gradually increases from a lower end toward an upper end of the resistive layer.

7. The resistive memory device of claim 6, wherein a density of vacancies per unit volume in the first resistive layer is greater than a density of vacancies per unit volume in the second resistive layer.

8. A method for manufacturing a resistive memory device, comprising:
forming a bottom electrode;
forming a first resistive layer which has an amorphous phase, over the bottom electrode;
forming a second resistive layer which has a polycrystal phase, over the first resistive layer; and
forming a top electrode over the second resistive layer.

9. The method of claim 8, wherein forming the first resistive layer is conducted through atomic layer deposition.

10. The method of claim 8, wherein forming the second resistive layer is conducted through physical vapor deposition or chemical vapor deposition.

11. The method of claim 8, wherein each of the first and second resistive layers comprises a transition metal oxide.

12. The method of claim 11, wherein the first and second resistive layers are formed of the same material or different materials.

13. The method of claim 11, wherein the transition metal oxide includes any one selected from the group consisting of a nickel oxide (NiO), a titanium oxide (TiO), a hafnium oxide (HfO), a niobium oxide (NbO), a zirconium oxide (ZrO), a tungsten oxide (WO) and a cobalt oxide (CoO).

14. The method of claim 8, wherein a thickness of the second resistive layer is the same as or greater than a thickness of the first resistive layer.
